(19) United States
(12) Patent Application Publication
(10) Pub. No.: US 2017/0327944 A1
(43) Pub. Date: Nov. 16, 2017

(54) ALUMINUM PRECURSORS FOR THIN-FILM DEPOSITION, PREPARATION METHOD AND USE THEREOF

(71) Applicants: JIANGNAN UNIVERSITY, Wuxi (CN); INSTITUTE OF MICROELECTRONICS, CHINESE ACADEMY OF SCIENCES, Beijing (CN)

(72) Inventors: Yuqiang DING, Wuxi (CN); Chao ZHAO, Kessel-lo (BE); Chongying XU, Bear (DE); Shuyan YANG, Wuxi (CN); Jinjuan XIANG, Beijing (CN); Hongyan MIAO, Wuxi (CN); Dawei WANG, Wuxi (CN)

(21) Appl. No.: 15/517,651

(22) PCT Filed: Sep. 17, 2015
(86) PCT No.: PCT/CN2015/089844

§ 371 Date: Apr. 7, 2017

(30) Foreign Application Priority Data
Oct. 10, 2014 (CN) 201410532553.1

(51) Int. Cl. C23C 16/20; C23C 16/455; C23C 16/40; C07F 5/06; C23C 16/18; C23C 16/08; C23C 16/448

(52) U.S. Cl. CPC C23C 16/20; C23C 16/45553; C23C 16/45534; C23C 16/4482; C07F 5/069; C23C 16/18; C23C 16/08; C23C 16/403

(57) ABSTRACT

Provided is an aluminum precursor for thin-film deposition having a structure of formula (I) or (II), wherein R₁, R₂, R₃, R₄, R₅, R₆, and R₇ each independently represent a hydrogen atom, C₁˜C₆ alkyl, halo-C₁˜C₆ alkyl, C₂˜C₅ alkenyl, halo-C₂˜C₅ alkenyl, C₃˜C₁₀ cycloalkyl, halo-C₃˜C₁₀ cycloalkyl, C₆˜C₁₀ aryl, halo-C₆˜C₁₀ aryl or —Si(R₀)₃, and wherein R₀ is C₁˜C₆ alkyl or halo-C₁˜C₆ alkyl. According to the present invention, based on the interaction principle between molecules, aluminum precursors for thin-film deposition are provided, which have a good thermal stability, are not susceptible to decomposition and convenient for storage and transportation, have good volatility at a high temperature, and are excellent in film formation.

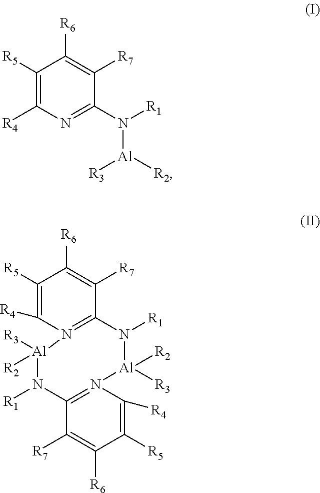

### TECHNICAL FIELD OF THE INVENTION

The present invention relates to an aluminum precursor useable for thin-film deposition, especially for atomic layer deposition, and the preparation method and the use thereof, and relates to the technical field of semiconductor and nano technology. More specifically, the present invention relates to an aluminum precursor for thin-film deposition having stable properties, being difficult to decomposition, excellent in volatility, and convenient for storage and transportation.

### BACKGROUND OF THE INVENTION

With the rapid development of semiconductor technologies, the processes and technologies for devices also evolve, thin films have been more widely used, and the processes for the manufacture of thin films have been improved correspondingly. Chemical vapor deposition (CVD) has many advantages over the conventional techniques, and in some fields, atomic layer deposition (ALD) technology is more advantageous.

In CVD/ALD technologies, the properties of precursors are critical. Under ambient temperature, the precursors should be highly stable for the convenient production, transportation, and storage, meanwhile they should have excellent volatility so as to allow them entering into a deposition chamber with carrier gases. In addition, CVD precursors should have a better property for thermal decomposition at a higher temperature (a deposition temperature) in order for the deposition of a suitable film; while ALD precursors should still be stable at a higher temperature (a deposition temperature) to avoid the thermal decomposition themselves and should have a good reactivity with another source in order the deposition of films. As the strict requirements on the properties of precursors such as their stability, volatility, and the like, there are few precursors truly suitable for the film formation. Thus, it becomes one of the critical techniques for CVD/ALD to develop suitable precursors.

For the deposition technologies of aluminum and aluminum-containing thin films, the stability of aluminum precursors has always been a technical challenge in the art. Abroad, U.S. patent application no. US 20030224152 A1 (2003) discloses a series of CVD precursors such as a complex of alkyl aluminum or alane with amine; patent application No. WO 2007/136184 A1 (2007) discloses a complex of amino boryl alane complex as CVD precursors. In ALD technologies, all the precursors used are those limited precursors used in CVD as mentioned above. Domestically, Chinese patent application no. 201310450417.3 discloses a method for the deposition of alumina film via ALD technology, in which the precursor is also alkyl aluminum (namely trimethyl aluminum). The above-mentioned aluminum precursors have good volatility and are widely used in existing CVD/ALD technologies, but they have following disadvantages:

(1) Being susceptible to thermal decomposition under ambient temperature, very unstable, being decomposed into hydrogen and metal aluminum during storage, the metal aluminum in turn catalyzes the decomposition reaction, having a risk of exploding, and thus being disadvantageous for storage, transportation, and subsequent application; and

(2) During the deposition of a thin film by ALD, CVD is concomitantly occurred due to the thermal decomposition of the precursors, which severely limits the advantages of ALD.

U.S. patent application no. US 20140017408 A1 (2014) discloses an aluminum precursor for use in CVD/ALD, this precursor is a complex of amino boryl alane complex, which can be used for the preparation of a Ti/Al alloy film, but it is complicated in the structure and difficult for production, meanwhile it has the two disadvantages listed above.

### SUMMARY OF THE INVENTION

The present invention is made in order to overcome the above-mentioned defects in the prior art. The technical problem solved by the present invention is to provide a series of aluminum precursors which are stable under ambient temperature, not susceptible to decomposition, convenient for storage and transportation, meanwhile good in volatility and no thermal decomposition in practical use, and thus suitable for ALD, and also to provide the preparation method and the use of such precursors.

The present invention provides an aluminum precursor for thin-film deposition having a structure represented by formula (I) or (II):

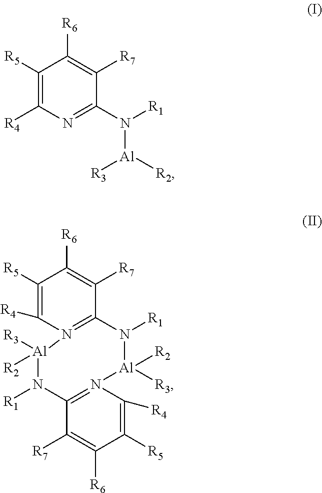

wherein R₁, R₂, R₃, R₄, R₅, R₆, and R₇ each independently represent a hydrogen atom, C₁˜C₆ alkyl, halo-C₁˜C₆ alkyl, C₂˜C₅ alkenyl, halo-C₂˜C₅ alkenyl, C₃˜C₁₀ cycloalkyl, halo-C₃˜C₁₀ cycloalkyl, C₆˜C₁₀ aryl, halo-C₆˜C₁₀ aryl or —Si(R₀)₃, and wherein R₀ is C₁˜C₆ alkyl or halo-C₁˜C₆ alkyl.

The present invention also provides a method for preparing the aluminum precursor for thin-film deposition described above, comprising the steps of:

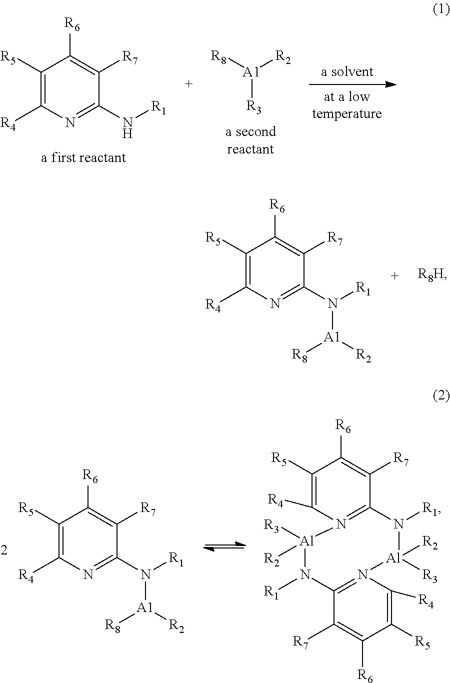

wherein R₁, R₂, R₃, R₄, R₅, R₆, and R₇ are as defined above, R₈ represents a hydrogen atom, C₁˜C₆ alkyl, halo-C₁˜C₆ alkyl, C₂˜C₅ alkenyl, halo-C₂˜C₅ alkenyl, C₃˜C₁₀ cycloalkyl, halo-C₃˜C₁₀ cycloalkyl, C₆˜C₁₀ aryl, halo-C₆˜C₁₀ aryl or —Si(R₀)₃, wherein R₀ is C₁˜C₆ alkyl or halo-C₁˜C₆ alkyl,

placing an amino pyridine or derivative thereof, as a first reactant, into a reaction vessel, to which a solvent is added and then is stirred uniformly; adding an alane, as a second reactant, to the reaction vessel under a low temperature condition, allowing the reaction to room temperature and stirring, followed by heating to reflux overnight, and then removing the solvent to obtain a colorless solution; purifying the solution by distillation, the fraction thus obtained is the aluminum precursor (I), which is left under room temperature to obtain an aluminum precursor (II).

Preferably, the temperature of the low temperature condition is −78° C. to 0° C., which, for example, is achieved by any one cooling means selected from liquid nitrogen, dry ice, liquid ammonia, and a cryo circulating pump, or a combination thereof.

Preferably, the time for stirring at room temperature is 1 to 8 hours.

Preferably, the temperature for heating to reflux overnight is 20 to 150° C.

Preferably, the feed molar ratio of the first reactant to the second reactant is from 1.0:1.0 to 1.0:2.0.

Preferably, the solvent is any one of organic solvents selected from straight or branched C₅H₁₂˜C₈H₁₈ alkanes, C₅H₁₀˜C₈H₁₆ cycloalkanes, benzene, toluene, ethyl ether and tetrahydrofuran, or a combination thereof.

Preferably, the temperature for purification by distillation is 60 to 190° C., and the distillation method includes any one of normal pressure distillation, reduced pressure distillation, and rectification, or a combination thereof.

The present invention further provides a method for preparing a semiconductor device, which comprises preparing an aluminum element-containing film made of the aluminum precursor described above by CVD or ALD, wherein the thin film includes any one of a metal aluminum thin film, an aluminum oxide-containing thin film, an aluminum nitride-containing thin film, and an aluminum alloy-containing thin film, or a combination thereof.

The advantageous effect of the present invention includes the following aspects:

(1) The introduction of amino pyridine ring as a ligand effectively decreases the reactivity of said precursor, and allows the formation of dimers having a higher molecular weight by complexation at ambient temperature, thus providing an increased stability, a decreased volatility, and the convenience for storage and transportation.

(2) The dimer turns back into the monomer precursor having a lower molecular weight when raising the temperature, and thus the volatility is increased and the film is easily formed by ALD.

(3) The synthesis process is simple, clean, low-cost in starting materials, low energy, and environment-friendly.

The aluminum precursors for thin-film deposition overcome effectively the defects in the prior art, increase the efficiency of thin-film deposition, and can be widely used in the fields of semiconductor and nano technology.

According to the present invention, based on the interaction principle between molecules, an aluminum precursor for thin-film deposition is researched and developed, which has a good thermal stability, is not susceptible to decomposition, is convenient for storage and transportation, has a good volatility under a high temperature, and is excellent in film formation.

### BRIEF DESCRIPTION OF DRAWINGS

The technical solutions of the present invention will be described in detail with reference to the accompanying figures in which:

FIG. 1 shows the thermogravimetric analysis spectrum of the dimer of 2-trimethylsilylaminopyridine dimethyl aluminum according to the present invention, wherein the spectrum analysis is performed as follows: the temperature for the starting point of weight loss is 101.9° C., the temperature corresponding to 50% weight loss is 148.7° C., the temperature for the end point of weight loss is 166.2° C., and the residual mass is −1.0%.

FIG. 2 shows the thermogravimetric analysis spectrum of the dimer of 2-trimethylsilylaminopyridine dimethyl aluminum according to the present invention, wherein the spectrum analysis is performed as follows: the temperature for the starting point of weight loss is 70.4° C., the temperature corresponding to 50% weight loss is 128.4° C., the temperature for the end point of weight loss is 146.8° C., and the residual mass is 1.4%.

FIG. 3 shows the thermogravimetric analysis spectrum of trimethylamine alane (TMAA) for comparison, wherein the spectrum analysis is performed as follows: the weight loss due to volatilization starts at room temperature, the temperature corresponding to 50% weight loss is 86.3° C., the temperature for the end point of weight loss is 111.5° C., and the residual mass is 6.2%.

FIG. 4 shows the thermogravimetric analysis spectrum of dimethylethylamine alane (DMEAA) for comparison, wherein the spectrum analysis is performed as follows: the weight loss due to volatilization starts at room temperature, the temperature corresponding to 50% weight loss is 115.1° C., the temperature for the end point of weight loss is 134.4° C., and the residual mass is 7.1%.

FIG. 5 shows the thermogravimetric analysis spectrum of dimethyl aluminum hydride (DMAH) for comparison, wherein the spectrum analysis is performed as follows: the weight loss due to volatilization starts at room temperature, the temperature corresponding to 50% weight loss is 124.9° C., the temperature for the end point of weight loss is greater than 200° C., and the residual mass is 26.6%.

### EMBODIMENTS OF THE INVENTION

The thin-film deposition precursors as described above are generally for use in various deposition films in the field of semiconductor and nano technology, such as aluminum film, alumina film, composite metal film, and nano thin film. The precursors provided by the present invention have good stability, are not susceptible to decomposition, are convenient for storage and transportation, have good volatility under a high temperature, and are excellent in film formation, and thus will facilitate the development of semiconductor and nano technology.

The present invention provides an aluminum precursor represented by formula (I):

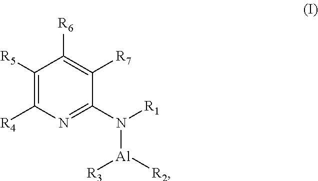

wherein R₁, R₂, R₃, R₄, R₅, R₆, and R₇ each independently represent a hydrogen atom, C₁˜C₆ alkyl, halo-C₁˜C₆ alkyl, C₂˜C₅ alkenyl, halo-C₂˜C₅ alkenyl, C₃˜C₁₀ cycloalkyl, halo-C₃˜C₁₀ cycloalkyl, C₆˜C₁₀ aryl, halo-C₆˜C₁₀ aryl or —Si(R₀)₃, and wherein R₀ is C₁˜C₆ alkyl or halo-C₁˜C₆ alkyl.

The precursor of formula (I) can be synthesized according to the following reaction scheme (1) of an amino pyridine or the derivative thereof and an alane which are both easily available:

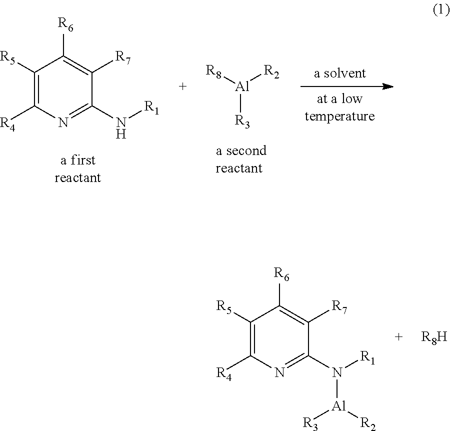

wherein R₁, R₂, R₃, R₄, R₅, R₆, R₇, and R₈ each independently represent a hydrogen atom, C₁˜C₆ alkyl, halo-C₁˜C₆ alkyl, C₂˜C₅ alkenyl, halo-C₂˜C₅ alkenyl, C₃˜C₁₀ cycloalkyl, halo-C₃˜C₁₀ cycloalkyl, C₆˜C₁₀ aryl, halo-C₆˜C₁₀ aryl or —Si(R₀)₃, and wherein R₀ is C₁˜C₆ alkyl or halo-C₁˜C₆ alkyl. The solvent is preferably, but not limited to (n-)hexane, and may also be other organic solvents, for example, straight or branched C₅H₁₂˜C₈H₁₈ alkanes, C₅H₁₀˜C₈H₁₆ cycloalkanes, arenes such as benzene, toluene, ethers such as ethyl ether, tetrahydrofuran, and the like.

As seen from the molecular structure, the aluminum atom in formula (I) is electron-deficient, being a Lewis acid, and the nitrogen atom on the pyridine ring has lone pair electron, being a Lewis base. With consideration of factors such as molecular tension, two molecules of the compound of formula (I) can form an acid-base complex represented by formula (II):

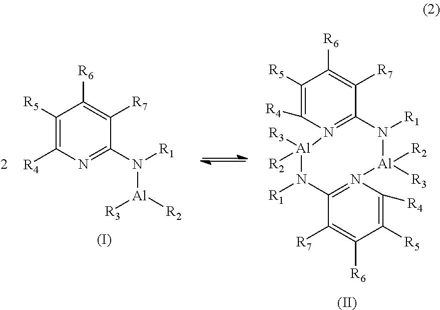

As the acid-base complex force between the two molecules is not quite strong, there is a chemical equilibrium between the compound of formula (I) and the compound of formula (II). As the compound of formula (I) has a relatively smaller molecular weight, it has high volatility. After the compounds of formula (I) is formed into the compound of formula (II) via complexation, it becomes a dimer having a relatively higher molecular weight, exhibiting a higher stability and lower volatility. When the temperature rising up, the coordination bond in the complex is broken, and the dimer of formula (II) turns back to the compound of formula (I), with volatility increased.

Based on the basic chemical principle mentioned above, the present invention provides a series of aluminum precursors as follows: reacting an amino pyridine or the derivative thereof, being cheap, with an alane, to give the aluminum precursor of formula (I) having good volatility; for the convenience of storage and transportation, forming the aluminum precursor into an acid-base complex, i.e., the compound of formula (II) having a high thermal stability and a low volatility under appropriate conditions; and, before use, heating the compound of formula (II) to convert it back to the aluminum precursor of formula (I) having good volatility.

The process for the preparation of the precursor of formula (I) and/or the compound of formula (II) comprises the steps of: placing amino pyridine or the derivative thereof, as a first reactant, into a reaction vessel, to which a solvent is added and then stirred them uniformly; adding slowly alane, as a second reactant, to the reaction vessel at a low temperature, allowing the reaction to room temperature and stirring, followed by heating to reflux overnight, and then removing the solvent (e.g., by low-pressure suction using a vacuum pump) to obtain a colorless solution; purifying the solution by distillation, the fraction thus obtained being the aluminum precursor (I); and, placing the precursor (I) at room temperature to obtain the aluminum precursor (II).

As used herein, the low temperature refers to a temperature below 0° C., and is preferably −78° C.˜0° C., it may specifically achieved by using media and devices for lowering temperature such as liquid nitrogen, dry ice, liquid ammonia, a cryo circulating pump, and the like. The temperature for heating the reaction system to reflux overnight and stirring is 20 to 150° C. The time for stirring at room temperature is preferably 1 to 8 hours, and varies depending on the kind of the reactants, i.e., amino pyridine or the derivative thereof and alane. Preferably, the molar ratio of the first reactant amino pyridine or the derivative thereof to the second reactant alane added is from 1.0:1.0 to 1.0:2.0. Preferably, the solvent is selected from organic solvents, e.g., alkanes such as straight or branched C₅H₁₂˜C₈H₁₈ alkanes, C₅H₁₀˜C₈H₁₆ cycloalkanes; arenes such as benzene, toluene; ethers such as ethyl ether, tetrahydrofuran, and the like. As to the purification by distillation, preferably, the distillation is performed at a temperature of 60 to 190° C., and according to the different products, the distillation method includes normal pressure distillation, reduced pressure distillation, rectification, and the like.

The thin films made of the aluminum precursor of (I) or (II) as described above by a CVD or ALD process may include aluminum-containing thin films such as aluminum film, alumina film, aluminum alloy film, and the like. Furthermore, the thin film thus obtained may find use in interlinkage between metal layers, contact plug, device terminals (source electrode, drain electrode, grid electrode), device high-K insulating layer (e.g., gate insulating layer of MOSFET).

The following Examples illustrate the preparation of the aluminum precursors of the present invention, 2-trimethylsilylaminopyridine dimethyl aluminum, 2-isopropylaminopyridine diisobutyl aluminum, 2-cyclohexylaminopyridine diisobutyl aluminum, 2-ethenylaminopyridine dimethyl aluminum, 2-phenylaminopyridine dimethyl aluminum, and 2-(1-bromoisopropyl)aminopyridine dimethyl aluminum, and compare them with trimethylamine alane (TMAA), dimethylethylamine alane (DMEAA), and dimethyl aluminum hydride (DMAH) in the prior art in terms of the property, which are intended to explain the present invention only, without limiting the scope of the present invention in any way.

### (1) Example 1

30.0 mmol of trimethylsilylaminopyridine was placed into a reaction vessel (a Schlenk flask with a magnetic stirrer), and 100 mL of n-hexane was then added thereto and stirred uniformly. Then, 30.0 mmol of trimethyl aluminum (TMA) was slowly added to the reaction system at a low temperature (−78° C.), air bubbles were generated without a significant change in color. The reaction system was allowed to room temperature and stirred for 3 h, and then heated to 60° C. for reflux overnight. Subsequently, the stirring was stopped, and the reaction was concentrated by removing the solvent under low pressure with a vacuum pump, to afford a colorless solution. The solution was then purified by distillation using a reduced pressure distillation device at 80° C. The fraction thus obtained was 2-trimethylsilylaminopyridine dimethyl aluminum (1#), which was placed under room temperature to form an acid-base complex, i.e., the solid dimer thereof.

### (2) Example 2

24.0 mmol of trimethylsilylaminopyridine was placed into a reaction vessel, and 100 mL of n-hexane was then added thereto and stirred uniformly. Then, 30.0 mmol of trimethyl aluminum (TMA) was slowly added to the reaction system at a low temperature (−65° C.), air bubbles were generated but without a significant change in color. The reaction system was allowed to room temperature and stirred for 4 h, and then heated to 70° C. for reflux overnight. Subsequently, the stirring was stopped, and the reaction system was concentrated by removing the solvent under reduced low pressure with a vacuum pump, to afford a colorless solution. The solution was then purified by distillation using a reduced pressure distillation device at 85° C. The fraction thus obtained was 2-trimethylsilylaminopyridine dimethyl aluminum (2#), which was placed under room temperature to form an acid-base complex, i.e., the solid dimer thereof.

### (3) Example 3

20.0 mmol of trimethylsilylaminopyridine was placed into a reaction vessel, and 100 mL of n-hexane was then added thereto and stirred uniformly. Then, 30.0 mmol of trimethyl aluminum (TMA) was slowly added to the reaction system at a low temperature (−50° C.), air bubbles were generated but without a significant change in color. The reaction system was allowed to room temperature and stirred for 5 h, and then heated to 75° C. for reflux overnight. Subsequently, the stirring was stopped, and the reaction system was concentrated by removing the solvent under reduced low pressure with a vacuum pump, to afford a colorless solution. The solution was then purified by distillation using a reduced pressure distillation device at 85° C. The fraction thus obtained was 2-trimethylsilylaminopyridine dimethyl aluminum (3#), which was placed under room temperature to form an acid-base complex, i.e., the solid dimer thereof.

### (4) Example 4

17.14 mmol of trimethylsilylaminopyridine was placed into a reaction vessel, and 100 mL of n-hexane was then added thereto and stirred uniformly. Then, 30.0 mmol of trimethyl aluminum (TMA) was slowly added to the reaction system at a low temperature (−35° C.), air bubbles were generated but without a significant change in color. The reaction system was allowed to room temperature and stirred for 5 h, and then heated to 80° C. for reflux overnight. Subsequently, the stirring was stopped, and the reaction system was concentrated by removing the solvent under reduced low pressure with a vacuum pump, to afford a colorless solution. The solution was then purified by distillation using a reduced pressure distillation device at 90° C. The fraction thus obtained was 2-trimethylsilylaminopyridine dimethyl aluminum (4#), which was placed under room temperature to form an acid-base complex, i.e., the solid dimer thereof.

### (5) Example 5

15.0 mmol of trimethylsilylaminopyridine was placed into a reaction vessel, and 100 mL of n-hexane was then added thereto and stirred uniformly. Then, 30.0 mmol of trimethyl aluminum (TMA) was slowly added to the reaction system at a low temperature (0° C.), air bubbles were generated but without a significant change in color. The reaction system was allowed to room temperature and stirred for 6 h, and then heated to 85° C. for reflux overnight. Subsequently, the stirring was stopped, and the reaction system was concentrated by removing the solvent under reduced low pressure with a vacuum pump, to afford a colorless solution. The solution was then purified by distillation using a reduced pressure distillation device at 90° C. The fraction thus obtained was 2-trimethylsilylaminopyridine dimethyl aluminum (5#), which was placed under room temperature to form an acid-base complex, i.e., the solid dimer thereof (5° #).

### (6) Example 6

30.0 mmol of 2-isopropylaminopyridine was placed into a reaction vessel, and 100 mL of n-hexane was then added thereto and stirred uniformly. Then, 30.0 mmol of triisobutyl aluminum was slowly added to the reaction system at a low temperature (−78° C.), air bubbles were generated but without a significant change in color. The reaction system was allowed to room temperature and stirred for 3 h, and then heated to 20° C. for reflux overnight. Subsequently, the stirring was stopped, and the reaction system was concentrated by removing the solvent under reduced low pressure with a vacuum pump, to afford a colorless solution. The solution was then purified by distillation using a reduced pressure distillation device at 80° C. The fraction thus obtained was 2-isopropylaminopyridine diisobutyl aluminum (6#), which was placed under room temperature to form an acid-base complex, i.e., the solid dimer thereof.

### (7) Example 7

24.0 mmol of 2-cyclohexylaminopyridine was placed into a reaction vessel, and 100 mL of n-hexane was then added thereto and stirred uniformly. Then, 30.0 mmol of triisobutyl aluminum was slowly added to the reaction system at a low temperature (−65° C.), air bubbles were generated but without a significant change in color. The reaction system was allowed to room temperature and stirred for 4 h, and then heated to 40° C. for reflux overnight. Subsequently, the stirring was stopped, and the reaction system was concentrated by removing the solvent under reduced low pressure with a vacuum pump, to afford a colorless solution. The solution was then purified by distillation using a reduced pressure distillation device at 85° C. The fraction thus obtained was 2-cyclohexylaminopyridine diisobutyl aluminum (7#), which was placed under room temperature to form an acid-base complex, i.e., the solid dimer thereof.

### (8) Example 8

20.0 mmol of 2-ethenylaminopyridine was placed into a reaction vessel, and 100 mL of n-hexane was then added thereto and stirred uniformly. Then, 30.0 mmol of dimethyl aluminum hydride (DMAH) was slowly added to the reaction system at a low temperature (−50° C.), air bubbles were generated but without a significant change in color. The reaction system was allowed to room temperature and stirred for 5 h, and then heated to 90° C. for reflux overnight. Subsequently, the stirring was stopped, and the reaction system was concentrated by removing the solvent under reduced low pressure with a vacuum pump, to afford a colorless solution. The solution was then purified by distillation using a reduced pressure distillation device at 85° C. The fraction thus obtained was 2-ethenylaminopyridine dimethyl aluminum (8#), which was placed under room temperature to form an acid-base complex, i.e., the solid dimer thereof.

### (9) Example 9

17.14 mmol of 2-phenylaminopyridine was placed into a reaction vessel, and 100 mL of n-hexane was then added thereto and stirred uniformly. Then, 30.0 mmol of trimethyl aluminum (TMA) was slowly added to the reaction system at a low temperature (−35° C.), air bubbles were generated but without a significant change in color. The reaction system was allowed to room temperature and stirred for 5 h, and then heated to 95° C. for reflux overnight. Subsequently, the stirring was stopped, and the reaction system was concentrated by removing the solvent under reduced low pressure with a vacuum pump, to afford a colorless solution. The solution was then purified by distillation using a reduced pressure distillation device at 90° C. The fraction thus obtained was 2-phenylaminopyridine dimethyl aluminum (9#), which was placed under room temperature to form an acid-base complex, i.e., the solid dimer thereof.

### (10) Example 10

15.0 mmol of 2-(1-bromoisopropyl)aminopyridine was placed into a reaction vessel, and 100 mL of n-hexane was then added thereto and stirred uniformly. Then, 30.0 mmol of trimethyl aluminum (TMA) was slowly added to the reaction system at a low temperature (0° C.), air bubbles were generated but without a significant change in color. The reaction system was allowed to room temperature and stirred for 6 h, and then heated to 50° C. for reflux overnight. Subsequently, the stirring was stopped, and the reaction system was concentrated by removing the solvent under reduced low pressure with a vacuum pump, to afford a colorless solution. The solution was then purified by distillation using a reduced pressure distillation device at 90° C. The fraction thus obtained was 2-(1-bromoisopropyl)aminopyridine dimethyl aluminum (10#), which was placed under room temperature to form an acid-base complex, i.e., the solid dimer thereof.

The thin film precursors prepared as described above (1#, 2#, 3#, 4#, 5#, 5° #, 6#, 7#, 8#, 9#, and 10#) were compared with the aluminum precursors in the prior art (TMAA, DMEAA, and DMAH), and the results were shown in Table 1 below and FIGS. 1 to 5.

TABLE 1

| | Temperature | Temperature | Temperature | |
|---|---|---|---|---|
| | for the starting | corresponding | for the end | |
| Aluminum | point of weight | to 50% weight | point of weight | Residual |
| precursors | loss (° C.) | loss (° C.) | loss (° C.) | mass (%) |
| 1# | 71.3 | 130.4 | 147.5 | 1.5 |
| 2# | 70.7 | 127.4 | 147.1 | 1.5 |
| 3# | 69.9 | 127.1 | 146.1 | 1.4 |
| 4# | 69.5 | 126.9 | 145.9 | 1.4 |
| 5# | 70.4 | 128.4 | 146.8 | 1.4 |
| 5⁰# | 101.9 | 148.7 | 166.2 | −1.0 |
| 6# | 70.9 | 126.3 | 145.4 | 1.3 |
| 7# | 69.1 | 129.6 | 147.8 | 1.5 |
| 8# | 68.9 | 128.7 | 146.5 | 1.5 |
| 9# | 70.5 | 128.0 | 146.3 | 1.4 |
| 10# | 71.0 | 129.9 | 147.0 | 1.3 |
| TMAA | RT | 86.3 | 111.5 | 6.2 |
| DMEAA | RT | 115.1 | 134.4 | 7.1 |
| DMAH | RT | 124.9 | >200 | 26.6 |

As can be seen from Table 1, TMAA, DMEAA, and DMAH all begin to volatilize at room temperature to lose weight, and their residual mass are all above 6.0%, even up to 26.6%, indicating that these three aluminum precursors are not stable and are susceptible to decomposition under a high temperature, and thus are relatively dangerous. In contrast, the aluminum precursors of the present invention begin to lose weight at a temperature of about 70° C., with a high volatility, and could form an acid-base complex under suitable conditions. For example, the precursor 5° # begins to lose weight at a temperature of 101.9° C., and had a residual mass as low as −1.0%, exhibiting a higher thermal stability and a lower volatility, and being convenient for storage and transportation. Raising temperature before use may result in a precursor with high volatility, being suitable for film formation by ALD.

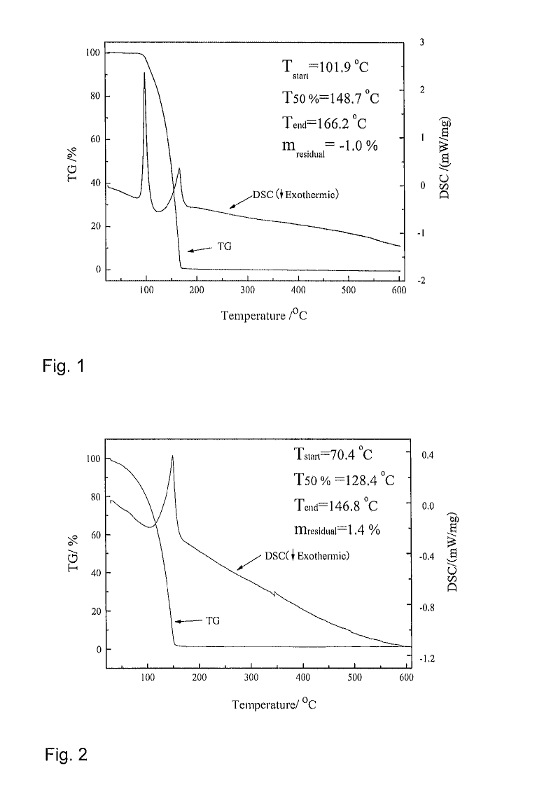

More specifically, taking sample 5# and its dimer 5° # as examples, FIG. 1 shows the thermogravimetric analysis spectrum of the dimer (5° #) of 2-trimethylsilylaminopyridine dimethyl aluminum according to the present invention, wherein the results of spectrum analysis are as follows: the temperature for the starting point of weight loss is 101.9° C., the temperature corresponding to 50% weight loss is 148.7° C., the temperature for the end point of weight loss is 166.2° C., and residual mass is −1.0%. FIG. 2 shows the thermogravimetric analysis spectrum of 2-trimethylsilylaminopyridine dimethyl aluminum according to the present invention (5#), wherein the results of spectrum analysis are as follows: the temperature for the starting point of weight loss is 70.4° C., the temperature corresponding to 50% weight loss is 128.4° C., the temperature for the end point of weight loss is 146.8° C., and residual mass is 1.4%.

As can be seen from FIG. 1 and FIG. 2, the precursor 2-trimethylsilylaminopyridine dimethyl aluminum begins to lose weight at around 70° C., with a good volatility, and can form solid dimer under suitable conditions, with a high stability and low volatility, being convenient for storage and transportation. When raising temperature up to 101.9° C., the solid dimer converts back to the liquid precursor, which may be maintained for a period of time and then the dimer can be formed again.

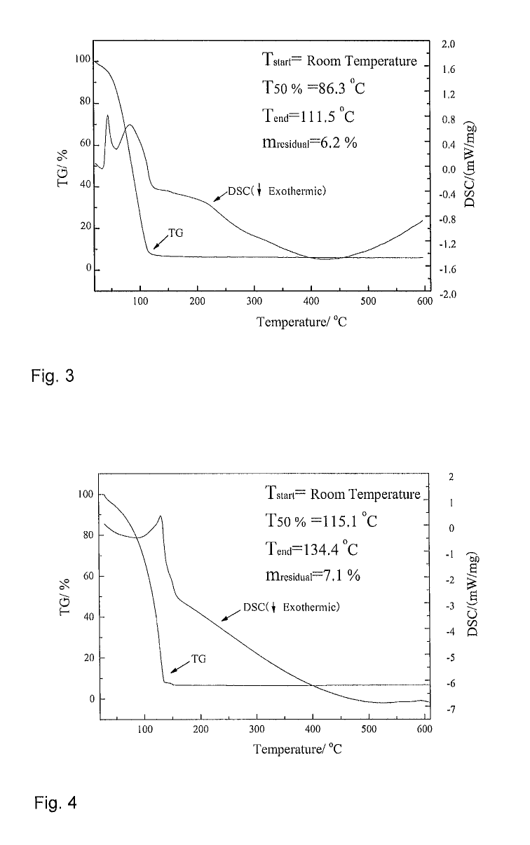

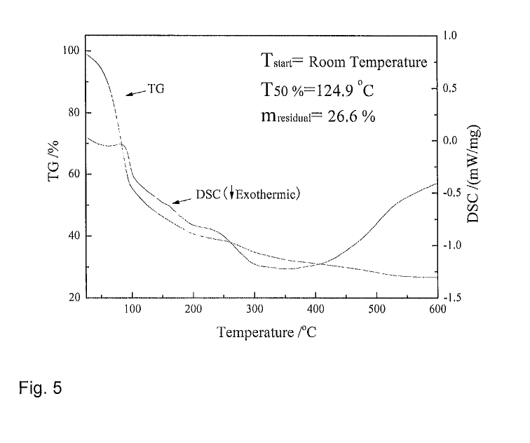

Furthermore, FIG. 3 shows the thermogravimetric analysis spectrum of trimethylamine alane (TMAA) for comparison, wherein the results of spectrum analysis are as follows: weight loss due to volatilization starts at room temperature, the temperature corresponding to 50% weight loss is 86.3° C., the temperature for the end point of weight loss is 111.5° C., and the residual mass is 6.2%. FIG. 4 shows the thermogravimetric analysis spectrum of dimethylethylamine alane (DMEAA) for comparison, wherein the results of spectrum analysis are as follows: weight loss due to volatilization starts at room temperature, the temperature corresponding to 50% weight loss is 115.1° C., the temperature for the end point of weight loss is 134.4° C., and the residual mass is 7.1%. FIG. 5 shows the thermogravimetric analysis spectrum of dimethyl aluminum hydride (DMAH) for comparison, wherein the results of spectrum analysis are as follows: weight loss due to volatilization starts at room temperature, the temperature corresponding to 50% weight loss is 124.9° C., the temperature for the end point of weight loss is greater than 200° C., and the residual mass is 26.6%.

The advantageous effects of the present invention include, but not limited to:

(1) The introduction of amino pyridine ring as a ligand effectively reduces the reactivity of precursors, and allows the formation of dimers having a higher molecular weight by complexation, thus providing increased stability, reduced volatility, and convenience for storage and transportation.

(2) The dimer turns back into the monomer precursor having a lower molecular weight when raising temperature, which has increased volatility and is easily for film formation by ALD.

(3) The synthetic process is simple, clean, low-cost in materials, low energy, and environment-friendly.

The aluminum precursors of the present invention for thin-film deposition overcome effectively the defects in the prior art, increases the efficiency of thin-film deposition, and can be widely applied to the fields of semiconductor and nano technology. According to the present invention, based on the interaction principle between molecules, aluminum precursors for thin-film deposition are provided, which have a good thermal stability, are not susceptible to decomposition, are convenient for storage and transportation, have good volatility under a high temperature, and are excellent in film formation.

Although the present invention has been described by one or more examples, it will be recognized by those skilled in the art that various modifications and equivalents of the process or materials can be made without departing from the scope of the present invention. Furthermore, based on the teaching disclosed herein, many possible modifications suitable for certain situation or materials can be made without departing from the scope of the present invention. It is not intended to limit the scope of the present invention to the specific examples disclosed as the optimal embodiments for carrying out the present invention. The materials, structures, chemical formulae, and preparation methods disclosed herein will include all examples that fall into the scope of the present invention.

1. An aluminum precursor for thin-film deposition having a structure of formula (I) or (II): 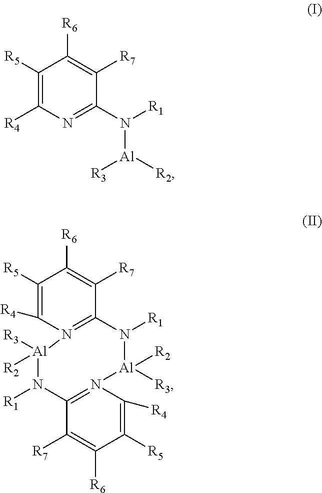
wherein R₁, R₂, R₃, R₄, R₅, R₆, and R₇ each independently represent a hydrogen atom, C₁˜C₆ alkyl, halo-C₁˜C₆ alkyl, C₂˜C₅ alkenyl, halo-C₂˜C₅ alkenyl, C₃˜C₁₀ cycloalkyl, halo-C₃˜C₁₀ cycloalkyl, C₆˜C₁₀ aryl, halo-C₆˜C₁₀ aryl or —Si(R₀)₃, and wherein R₀ is C₁˜C₆ alkyl or halo-C₁˜C₆ alkyl.

2. The aluminum precursor for thin-film deposition according to claim 1, wherein R₁ is C₁˜C₆ alkyl, halo-C₁˜C₆ alkyl, C₂˜C₅ alkenyl, C₃˜C₁₀ cycloalkyl, C₆˜C₁₀ aryl or —Si(R₀)₃, R₂ and R₃ are C₁˜C₆ alkyl, and R₄, R₅, R₆, and R₇ each independently are a hydrogen atom or C₁˜C₆ alkyl.

3. The aluminum precursor for thin-film deposition according to claim 1, wherein, R₁ is isopropyl, cyclohexyl, ethenyl, haloisopropyl or —Si(R₀)₃, R₂ and R₃ each independently are methyl or isobutyl, R₄, R₅, R₆, and R₇ are a hydrogen atom, and R₀ is methyl.

4. A method for preparing the aluminum precursor for thin-film deposition according to claim 1, the method comprising: 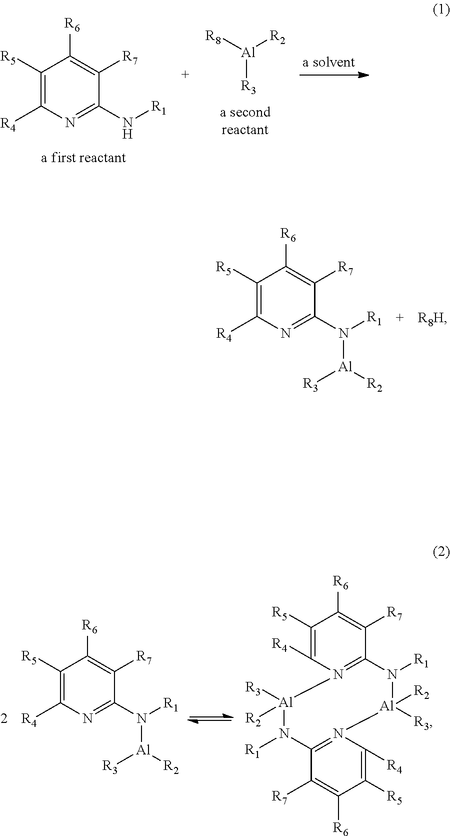
wherein R₁, R₂, R₃, R₄, R₅, R₆, and R₇ are as defined in claim 1, and R₃ represents a hydrogen atom, C₁˜C₆ alkyl, halo-C₁˜C₆ alkyl, C₂˜C₅ alkenyl, halo-C₂˜C₅ alkenyl, C₃˜C₁₀ cycloalkyl, halo-C₃˜C₁₀ cycloalkyl, C₆˜C₁₀ aryl, halo-C₆˜C₁₀ aryl or —Si(R₀)₃,
placing an amino pyridine or the derivative thereof, as a first reactant, into a reaction vessel, and a solvent is then added thereto and stirred uniformly;
adding an alane, as a second reactant, to the reaction vessel at a temperature below room temperature, allowing the reaction system to reach room temperature and stirring the reaction system before heating to reflux, and then removing the solvent to obtain a solution;
purifying the solution by distillation, and the fraction thus obtained being aluminum precursor (I); and
placing the precursor (I) under room temperature to obtain aluminum precursor (II).

5. The method according to claim 4, wherein the low temperature below room temperature is selected from −78° C. to 0° C.

6. The method according to claim 4, wherein the stirring is performed at room temperature for a time selected from 1 to 8 hours.

7. The method according to claim 4, wherein the temperature for heating to reflux is selected from 20 to 150° C.

8. The method according to claim 4, wherein the molar ratio of the first reactant to the second reactant is selected from 1.0:1.0 to 1.0:2.0.

9. The method according to claim 4, wherein the solvent is selected from: straight or branched C₅H₁₂˜C₈H₁₈ alkane, C₅H₁₀˜C₈H₁₆ cycloalkane, benzene, toluene, ethyl ether and tetrahydrofuran, or any combination selected from the foregoing.

10. The method according to claim 4, wherein the distillation is performed at a temperature selected from 60 to 190° C. and the distillation includes normal pressure distillation, reduced pressure distillation, rectification, or any combination selected from the foregoing.

11. A method for preparing a semiconductor device comprising: forming an aluminum element-containing thin film, the thin film being made of the aluminum precursor as defined in claim 1 by chemical vapor deposition or atomic layer deposition, wherein the thin film comprises metal aluminum thin film, aluminum oxide-containing thin film, aluminum nitride-containing thin film, aluminum alloy-containing thin film, or any combination selected from the foregoing.

12. A method of preparing an aluminum precursor for thin-film deposition, the method comprising:
combining an alane, as a first reactant, with an amino pyridine or a derivative thereof, as a second reactant, to obtain an aluminum precursor according to formula (I) below;
having the precursor according to formula (I) be at room temperature to obtain an aluminum precursor according to formula (II) below, 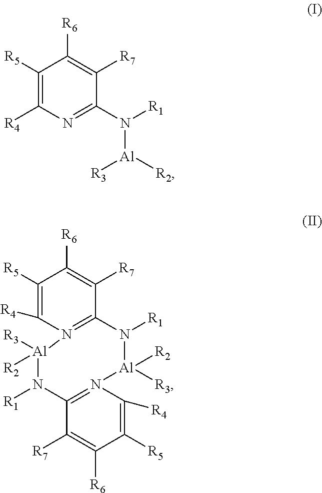
wherein R₁, R₂, R₃, R₄, R₅, R₆, and R₇ each independently represent a hydrogen atom, C₁˜C₆ alkyl, halo-C₁˜C₆ alkyl, C₂˜C₅ alkenyl, halo-C₂˜C₅ alkenyl, C₃˜C₁₀ cycloalkyl, halo-C₃˜C₁₀ cycloalkyl, C₆˜C₁₀ aryl, halo-C₆˜C₁₀ aryl or —Si(R₀)₃, and wherein R₀ is C₁˜C₆ alkyl or halo-C₁˜C₆ alkyl.

13. The method according to claim 12, wherein R₁ is C₁˜C₆ alkyl, halo-C₁˜C₆ alkyl, C₂˜C₅ alkenyl, C₃˜C₁₀ cycloalkyl, C₆˜C₁₀ aryl or —Si(R₀)₃, R₂ and R₃ are C₁˜C₆ alkyl, and R₄, R₅, R₆, and R₇ each independently are a hydrogen atom or C₁˜C₆ alkyl.

14. The method according to claim 12, wherein, R₁ is isopropyl, cyclohexyl, ethenyl, haloisopropyl or —Si(R₀)₃, R₂ and R₃ each independently are methyl or isobutyl, R₄, R₅, R₆, and R₇ are a hydrogen atom, and R₀ is methyl.

15. The method according to claim 12, wherein the first and second reactants are combined at a temperature below room temperature, and then the combination of the first and second reactants is allowed to reach at least room temperature

16. The method according to claim 15, wherein the temperature below room temperature is selected from −78° C. to 0° C.

17. The method according to claim 12, further comprising stirring the first and second reactants before heating to reflux, wherein the stirring is performed at room temperature for a time selected from 1 to 8 hours.

18. The method according to claim 12, further comprising purifying the combination of the first and second reactants by distillation, and the fraction thus obtained being the aluminum precursor according to formula (I).

19. The method according to claim 18, wherein the distillation is performed at a temperature selected from 60 to 190° C. and the distillation includes normal pressure distillation, reduced pressure distillation, rectification, or any combination selected from the foregoing.

20. The method according to claim 12, wherein the molar ratio of the second reactant to the first reactant is selected from 1.0:1.0 to 1.0:2.0.
